(19) United States
(12) Patent Application Publication
(10) Pub. No.: US 2007/0139898 A1
(43) Pub. Date: Jun. 21, 2007

(54) System motherboard having expansibility and variability

(75) Inventor: Ji Chi Yang, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/303,380

(22) Filed: Dec. 16, 2005

(51) Int. Cl. H05K 7/00

(52) U.S. Cl. 361/760

(57) ABSTRACT

A system motherboard having expansibility and variability includes a first circuit board provided with a system chipset and a second circuit board provided with a CPU, and the first circuit board and the second circuit board are electrically connected by a connector, so that the system motherboard has greater expansibility and flexibility in replacing components on the system motherboard. Further, when the first circuit board is replaced with a new one, it may be conveniently tested by using the second circuit board.

### FIELD OF THE INVENTION

The present invention relates to system motherboards with function expansibility, and more particularly, to system motherboards having expansibility and variability by using high frequency connectors.

### BACKGROUND OF THE INVENTION

Motherboard is the biggest circuit board in a computer, which provides installation slots for CPU, memory, and various functional cards and provides communication interface for various I/O devices, multimedia devices, and communication devices. A complete system of a computer is formed by connecting various components, such as CPU, with external devices by the motherboard. In addition, control of system memory, storage elements, and other I/O devices must be achieved through the motherboard.

According to different requirements of users and application fields, motherboards are designed in different types, mainly are: desktop motherboards and server/workstation motherboards. A desktop motherboard is a motherboard applied to a personal computer, and the model of such motherboard is ATX or Micro ATX structure, using normal power supply. A server/workstation motherboard is a motherboard specially applied to a server/workstation, and the model of the motherboard is larger ATX, EATX, or WATX structure, using specialized power supply for servers.

HyperTransport, an interconnection technique capable of supporting high-speed and high-performance peer-to-peer connection, is designed to fulfill the bandwidth requirement of next-generation computers and communication platforms. It is not only advantageous in decreasing the number of buses, but also ensure high-performance connections of personal computers, workstations, servers, various different embedded application solutions and highly flexible multi-processors systems. Further, the HyperTransport technique may ensure that personal computer chips, network, and communication devices may communicate in a speed up to 48 times faster than some current bus techniques. Therefore, the HyperTransport technique provides higher compatibility and more bandwidth.

Referring to FIG. 1, a traditional system motherboard 1 includes a Northbridge 111, a Southbridge 112, CPUs 121, and other components (e.g. storage elements 122) installed thereon. Connections between the two CPUs 121, one of the CPUs 121 and the Northbridge 111, and one of the CPUs 121 and the Southbridge 112 are provided via HyperTransport buses 13.

The drawback of the above system motherboard 1 is that when there is a need to replace with a new CPU 121 model or upgrade a storage element 122 from DDR to DDRII, and since different CPU 121 and storage-element 122 models require different types of slots, the entire circuit board needs to be replaced. Further, the motherboard 1 shown in FIG. 1 is a Symmetrical Multi-Processing (SMP) (or 2P) system, that is, has two CPUs 121 with the same model and operating frequency. If the system motherboard 1 needs to be expanded to a 4P system, the number of CPU slots on the motherboard 1 has to be increased. However, such design infrastructure limits the expansibility of the motherboard 1, such that the entire circuit board also needs to be replaced.

Therefore, there is a need for a motherboard structure with greater expansibility and flexibility that allows individually replacement of components on the circuit board without affecting other components and without the need for replacing the entire circuit board.

### SUMMARY OF THE INVENTION

In light of the above drawbacks in the prior art, an objective of the present invention is to provide a system motherboard to enhance expansibility thereof.

Another objective of the present invention is to provide a system motherboard to allow individually replacement of the related components without affecting other components, so as to make the replacement operation of components on the system motherboard more flexible.

Yet another objective of the present invention is to provide a system motherboard to test a newly-installed system chipset by using a circuit board provided with a CPU.

In accordance with the above and other objectives, the present invention proposes a system motherboard having expansibility and variability comprising a first circuit board provided with at least one system chipset thereon; a second circuit board provided with at least one CPU thereon; and a connector for connecting the first circuit board with the second circuit board.

In a preferred embodiment, the system chipset comprises a Southbridge and a Northbridge.

In another preferred embodiment, the first circuit board further comprises a HyperTransport bus for electrically connecting the system chipset with the connector.

In still another preferred embodiment, the CPUs on the second circuit board are connected via a HyperTransport bus.

In comparison to the prior art, the system motherboard having expansibility and variability of the present invention mainly separates the system chipset and CPU(s) into two individual circuit boards and electrically connect these two circuit boards by a high frequency connector to enhance the expansibility and replacement flexibility of the system motherboard and consequently reduce production cost. Further, it facilitates testing of newly installed components.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a schematic diagram showing a conventional structure of system motherboard; and

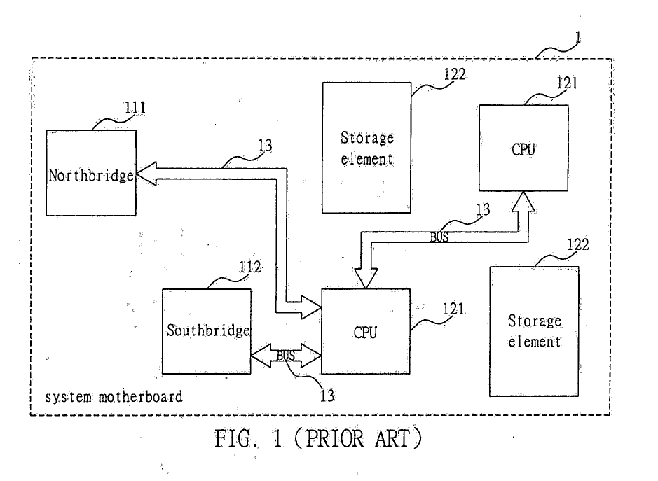

FIG. 2 is a schematic diagram showing the structure of the system motherboard having expansibility and variability according to the present invention.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

It should be noted that the drawings are simplified diagrams for illustrating the basic structure of the present invention. Therefore, only elements related to the present invention are depicted in the drawings, and the depicted elements are not drawn to actual amount, shape, size ratio, and so on, which are only a matter of design choices in actual implementation.

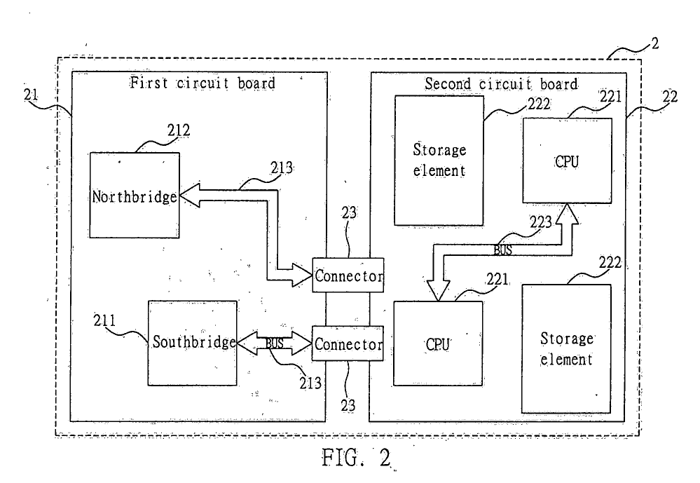

Referring to FIG. 2, a block diagram showing the structure of a system motherboard 2 having expansibility and variability according to an embodiment of the present invention. The system motherboard 2 according to the present invention as shown in FIG. 2 comprises a first circuit board 21, a second circuit board 22, and connectors 23. In this embodiment, the system motherboard 2 of the present invention is applied to an information equipment, such as a personal computer, workstation, and so on.

The first circuit board 21 is provided with a system chipset that comprises a Southbridge 211 and a Northbridge 212, wherein the north bridge chip 212 supports a Peripheral Component Interconnect eXtended (PCI-X) bus interface. The data transmission of the system motherboard 2 of the present invention is performed by connecting the Southbridge 211 and the North bridge chip 212 to respective connectors 23 via respective HyperTransport buses 213.

The second circuit board 22 is provided with at least one CPU 221. In this embodiment, two CPUs 221 with the same model and operating frequency are provided on the second circuit board 22, that is, the system motherboard 2 is a 2P system, and the two CPUs 221 are also connected via a HyperTransport bus 223. Further, the second circuit board 22 provides storage elements 222, such as SRAM, DRAM, DDR-RAM, DDR2-RAM, and so on.

The connectors 23 are high frequency connectors and electrically connect the first circuit board 21 and the second circuit board 22.

The system motherboard 2 therefore has the following effects:

1. Enhance the expansibility of the system motherboard. If there is a need to expand the motherboard in the current embodiment to a four-processor system, a user only needs to connect another second circuit board 22 to the system motherboard 2 using another connector 23.

2. Enhance flexibility in upgrading components of the system motherboard 2. If the user needs to replace the CPU 221 with another model type while maintaining the other system chipsets, then the user only needs to replace the second circuit board 22. Similarly, if the user needs to upgrade with a newer set of system chipset, then only the first circuit board 21 needs to be replaced.

3. Facilitate testing. According to the above, after the system chipset is replaced, the user may test the functionality of the replaced system chipset and the HyperTransport bus by using the second circuit board 2 provided with CPUs 221.

Although the foregoing embodiments are chosen and described in order to best explain the principles of the invention and its practical application, it is not intended to limit the scope of the present invention, but rather to enable others skilled in the art to best understand and utilize the invention with various modifications as are suited to the particular use contemplated. The scope of the invention is defined by the following claims and their equivalents.

1: A system motherboard having expansibility and variability, comprising:
a first circuit board provided with at least one system chipset thereon, the system chipset comprising a Southbridge and a Northbridge;
a second circuit board provided with at least one central processing unit (CPU) thereon;
a connector for connecting the first circuit board with the second circuit board;
another second circuit board provided with another CPU thereon; and
another connector for connecting the first circuit board with the another second circuit board.

2. (canceled)

3: The system motherboard of claim 1, wherein the first circuit board further comprises a HyperTransport bus for electrically connecting the system chipset with the connector.

4: The system motherboard of claim 1, wherein the CPUs on the second circuit board are connected via a HyperTransport bus.

5: The system motherboard of claim 1, wherein the connector is a high frequency connector.
